(19) United States
(12) Patent Application Publication
(10) Pub. No.: US 2014/0144377 A1
(43) Pub. Date: May 29, 2014

(54) SUBSTRATE AND MASK ATTACHMENT CLAMP DEVICE

(71) Applicant: INDUSTRIAL TECHNOLOGY RESEARCH INSTITUTE, Chutung (TW)

(72) Inventors: Chen-Chung Du, Hsinchu City (TW); Muh-Wang Liang, Toufen Township (TW); Yuan-Yuan Chiang, Taichung City (TW)

(73) Assignee: INDUSTRIAL TECHNOLOGY RESEARCH INSTITUTE, Chutung (TW)

(21) Appl. No.: 13/872,721

(22) Filed: Apr. 29, 2013

(30) Foreign Application Priority Data
Nov. 29, 2012 (TW) 101144733

(51) Int. Cl. C23C 16/458; F16B 2/12

(52) U.S. Cl. CPC C23C 16/458; F16B 2/12
USPC 118/504; 24/528

(57) ABSTRACT

A substrate and mask attachment clamp device comprising a push assembly, an upper clamp mechanism and a lower clamp mechanism is disclosed. The upper clamp mechanism comprises a first inclined surface, a swing element, a second inclined surface and a sliding surface. The lower clamp mechanism comprises a lower clamp retainer and a clamp movably. During the push assembly moving along a first direction, the push assembly moves with respect to the first inclined surface to drive the upper clamp mechanism to move along a second direction. The push assembly further drives the second inclined surface to move with respect to the swing element, so that the swing element drives the clamp to move along a third direction opposite to the first direction, and drives the sliding surface to move with respect to the lower clamp mechanism to drive the clamp to move along a fourth direction.

This application claims the benefit of Taiwan application Serial No. 101144733, filed Nov. 29, 2012, the disclosure of which is incorporated by reference herein in its entirety.

### TECHNICAL FIELD

The disclosure relates in general to a substrate and mask attachment clamp device, and more particularly to a mechanic type substrate and mask attachment clamp device.

### BACKGROUND

In a conventional evaporation process, a substrate is fixed on a mask by a magnetic force, and then the substrate is coated. However, during the process of physical vapor deposition (PVD) or plasma enhanced chemical vapor deposition (PECVD), magnetic force may easily affect the plasma field during the manufacturing process. Consequently, the uniformity of the coating on the substrate will be poor.

### SUMMARY

The disclosure is directed to a substrate and mask attachment clamp device, which is a mechanic type clamp device not affecting the plasma distribution during the manufacturing process.

According to one embodiment, a substrate and mask attachment clamp device is disclosed. The substrate and mask attachment clamp device comprises a push assembly, an upper clamp mechanism and a lower clamp mechanism. The upper clamp mechanism comprises a first reciprocating assembly and a second reciprocating assembly. The first reciprocating assembly comprises a first inclined surface and a swing element. The second reciprocating assembly comprises a second inclined surface and a sliding surface. The lower clamp mechanism comprises a lower clamp retainer and a clamp movably disposed on the lower clamp retainer. During the process of the push assembly moving along a first direction, the push assembly drives a first inclined surface to generate a bevel movement, which drives the first reciprocating assembly to move along a second direction. The push assembly drives the second inclined surface and the swing element to generate a bevel movement, so that the swing element drives the clamp to move along a third direction opposite to the first direction. The push assembly further drives the sliding surface to move with respect to the lower clamp mechanism so as to drive the clamp to move along a fourth direction. The first direction, the second direction and the fourth direction are perpendicular to each other.

### BRIEF DESCRIPTION OF THE DRAWINGS

FIG. 1 shows an appearance diagram of a substrate and mask attachment clamp device according to an embodiment of the disclosure;

FIG. 2 shows an appearance diagram of a substrate of FIG. 1 being clamped by a mask assembly;

FIG. 3 shows a schematic diagram of a lower clamp mechanism of FIG. 1 entering an upper clamp mechanism;

FIG. 4 shows an appearance diagram of an upper clamp mechanism of FIG. 1;

FIG. 5 shows an appearance diagram of a lower clamp mechanism of FIG. 1;

FIG. 6 shows a partial enlargement of the lower clamp mechanism and the upper clamp mechanism of FIG. 3;

FIG. 7 shows a schematic diagram of the first reciprocating assembly of FIG. 6 moving along the second direction.

FIG. 8 shows an appearance diagram of the second reciprocating assembly of FIG. 4;

FIG. 9 shows a schematic diagram of a push assembly of FIG. 7 driving the second reciprocating assembly to generate a bevel movement;

FIG. 10 shows a side view towards the −X axial direction of FIG. 9; and

FIG. 11 shows a schematic diagram of a push assembly of FIG. 10 pushing the clamp to move along the fourth direction.

In the following detailed description, for the purposes of explanation, numerous specific details are set forth in order to provide a thorough understanding of the disclosed embodiments. It will be apparent, however, that one or more embodiments may be practiced without these specific details. In other instances, some well-known structures and devices are schematically shown in order to simplify the drawing.

### DETAILED DESCRIPTION

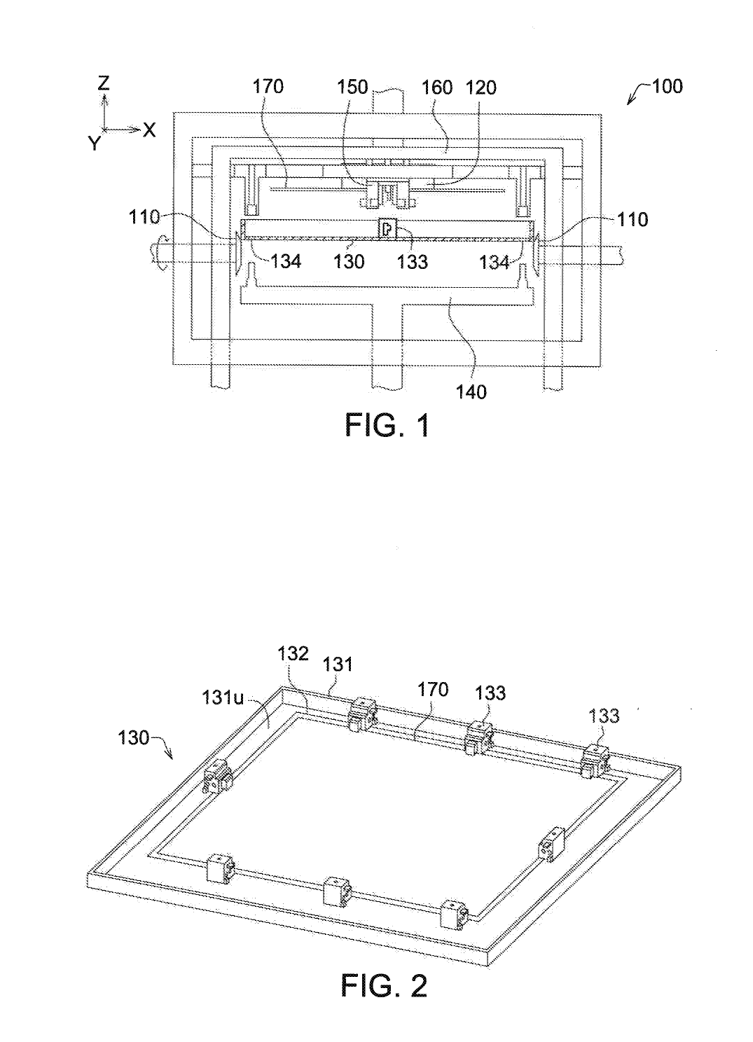

Referring to FIG. 1, an appearance diagram of a substrate and mask attachment clamp device according to an embodiment of the disclosure is shown. The substrate and mask attachment clamp device 100 is a mechanic clamp device not affecting the uniformity of plasma distribution during the manufacturing process. The substrate and mask attachment clamp device 100 comprises a transmission mechanism 110, an electrostatic chuck 120, a mask assembly 130, an up-lifting component 140, at least one upper clamp mechanism 150 and a push assembly 160.

The transmission mechanism 110, being a roller transmission mechanism, can transmit the mask assembly 130 to the underneath of the upper clamp mechanism 150 along the Y axial direction. After the substrate 170 is clamped on the mask assembly 130 by an attaching clamp, the transmission mechanism 110 further transmits the mask assembly 130 containing the substrate 170 to a coating device (not illustrated) for subsequent coating treatment. Examples of the coating treatment are such as chemical evaporation, physical vapor deposition, plasma enhanced chemical vapor deposition or other coating processes which may use magnetic force to hold substrates. In another example, the transmission mechanism 110 may also be realized by other transmission mechanisms such as a conveyor mechanism.

The electrostatic chuck 120 may hold the substrate 170 first, and then place the substrate 170 into the mask assembly 130 after the upper clamp mechanism 150 and the mask assembly 130 are integrated.

Referring to FIG. 2, an appearance diagram of a substrate of FIG. 1 being clamped by a mask assembly is shown. The mask assembly 130 comprises a frame 131, a mask 132 and at least one lower clamp mechanism 133 (denoted by bold lines). The frame 131 has a non-coating surface 131u, a mask 132 and a lower clamp mechanism 133. The lower clamp mechanism 133 is disposed onto the non-coating side 131u of the frame 131. The lower clamp mechanism 133 disposed on the edge of the frame 131 may clamp the edge of the substrate 170.

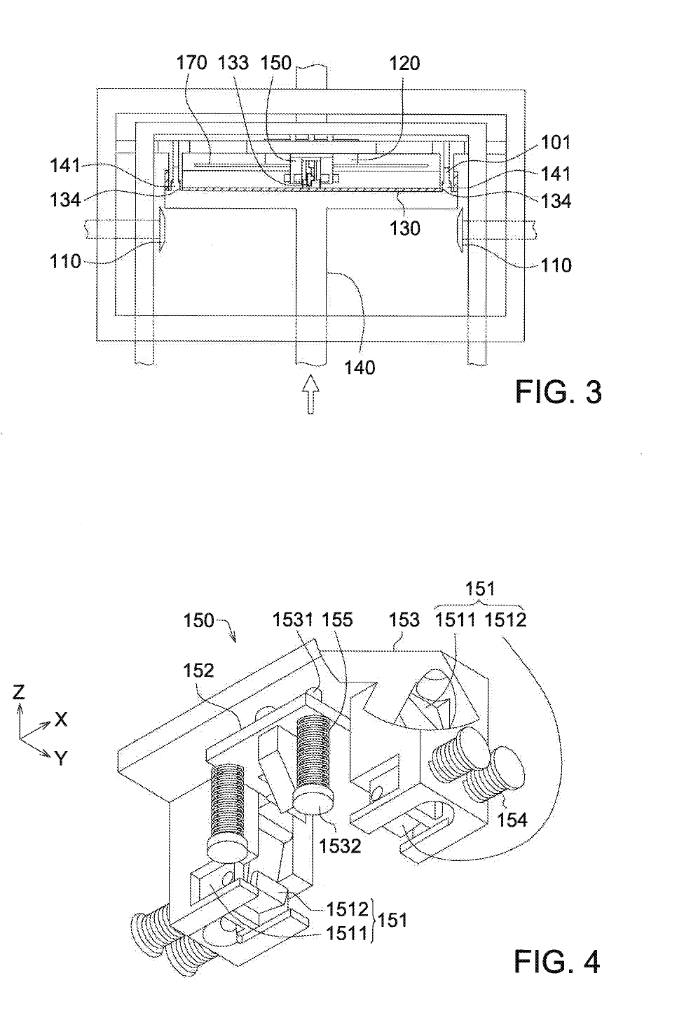

Referring to FIG. 3, a schematic diagram of a lower clamp mechanism of FIG. 1 entering an upper clamp mechanism is shown. The up-lifting component 140 comprises at least one protruded portion 141. The mask assembly 130 has at least one hole 134. The protruded portion 141 of the up-lifting component 140 passes through the hole 134 of the mask assembly 130 to lift the mask assembly 130 to proceed towards the upper clamp mechanism 150 until the lower clamp mechanism 133 enters the upper clamp mechanism 150. When the lower clamp mechanism 133 enters the upper clamp mechanism 150, the protruded portion 141 of the up-lifting component 140 enters the engaging hole 101 of the substrate and mask attachment clamp device 100 and becomes engaged therein for fixing the mask assembly 130.

Referring to FIG. 4, an appearance diagram of an upper clamp mechanism of FIG. 1 is shown. The upper clamp mechanism 150 comprises at least one first reciprocating assembly 151, a second reciprocating assembly 152, an upper body 153, a first elastic member 154 and a second elastic member 155.

The first reciprocating assembly 151 and the second reciprocating assembly 152 can be movably disposed on the upper body 153 with respect to the upper body 153. In the present example, each upper clamp mechanism 150 comprises two sets of first reciprocating assembly 151 respectively located on two opposite sides of the second reciprocating assembly 152.

The first elastic member 154 connects the first reciprocating assembly 151 with the upper body 153. When the first reciprocating assembly 151 is driven to move with respect to the upper body 153, the first elastic member 154 is deformed and stores the elastic potential energy. After the first reciprocating assembly 151 is released, the first elastic member 154 is released and drives the first reciprocating assembly 151 to return to the initial position. The second elastic member 155 connects the second reciprocating assembly 152 with the upper body 153. When the second reciprocating assembly 152 is driven to move with respect to the upper body 153, the second elastic member 155 is deformed and stores the elastic potential energy. After the second reciprocating assembly 152 is released, the second elastic member 155 is released and drives the second reciprocating assembly 152 to return to the initial position.

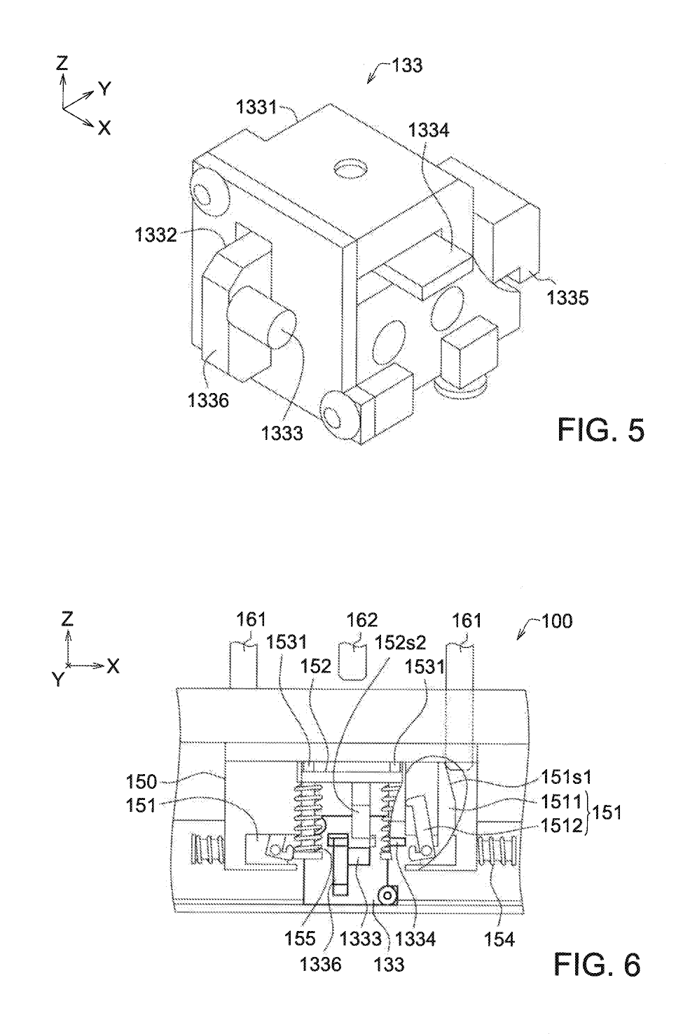

Referring to FIG. 5, an appearance diagram of a lower clamp mechanism of FIG. 1 is shown. The lower clamp mechanism 133 comprises a lower clamp retainer 1331, a clamp 1332, a cylinder structure 1333 and a protruded structure 1334. The clamp 1332, movably disposed and passing through the lower clamp retainer 1331, comprises a clamp end 1335 and a tail end 1336, wherein the clamp end 1335 and the tail end 1336 are protruded from the lower clamp retainer 1331. The cylinder structure 1333 is disposed on the tail end 1336. The two ends of the protruded structure 1334 (only one end is illustrated in FIG. 5) are protruded from the lower clamp retainer 1331 and connected to the clamp 1332. The extending direction of the protruded structure 1334 and the extending direction of the cylinder structure 1333 are the same axial direction (such as the X axial direction) substantially perpendicular to the extending direction of the clamp 1332. For example, the clamp is extended along the Y axial direction, and the protruded structure is extended along the X axial direction.

Referring to FIG. 6, a partial enlargement of the lower clamp mechanism and the upper clamp mechanism of FIG. 3 is shown. The first reciprocating assembly 151 comprises a horizontal slide member 1511 and a swing element 1512, wherein the horizontal slide member 1511 is pivotally connected to the swing element 1512 and has a first inclined surface 151s1. In the present example, the first inclined surface 151s1 can be realized by a plane or a curved surface.

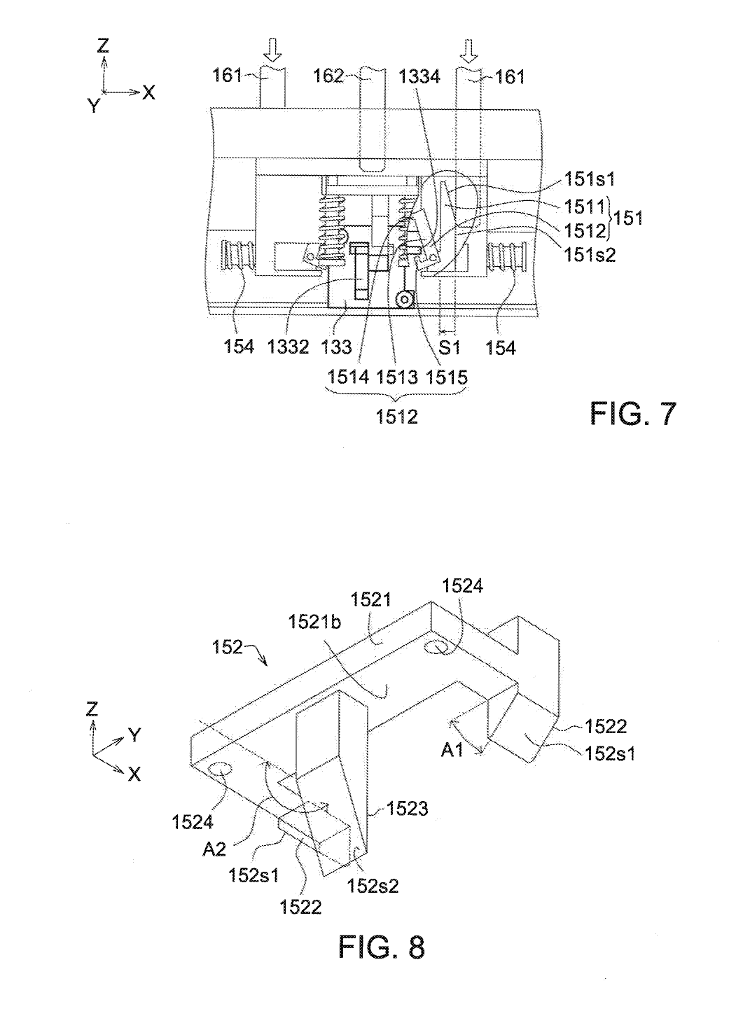

The push assembly 160 (illustrated in FIG. 7) comprises at least one first push member 161 and a second push member 162. After the lower clamp mechanism 133 enters the upper clamp mechanism 150, the first push member 161 pushes the first inclined surface 151s1 along a first direction (such as the −Z axial direction), and drives the horizontal slide member 1511 to move along a second direction (such as the −X axial direction), wherein the second direction faces the lower clamp mechanism 133 and is the X axial direction in the present example. During the process of the first push member 161 of the push assembly 160 moving along the first direction (the −Z axial direction), the first push member 161 drives the first inclined surface 151s1 to generate a bevel movement, which drives the horizontal slide member 1511 of the first reciprocating assembly 151 to move for a distance S1 along the second direction (the −X axial direction).

Referring to FIG. 7, a schematic diagram of a first reciprocating assembly of FIG. 6 moving along the second direction is shown. When the first push member 161 continues to move along the first direction until touching the surface 151s2 of the horizontal slide member 1511, the horizontal slide member 1511 stops moving along the second direction, thereby controlling the displacement and limit position of the horizontal slide member 1511. Here, the surface 151s2 refers to the coplanar surface of the extending direction and the first direction.

During the process of the horizontal slide member 1511 moving for a distance S1 along the second direction (the −X axial direction), the first elastic member 154 is deformed and stores the elastic potential energy. After the first push member 161 moves along a third direction (such as the +Z axial direction) opposite to the first direction and come off the horizontal slide member 1511, the first elastic member 154 releases the elastic potential energy, and drives the horizontal slide member 1511 to return to the initial position (the position as indicated in FIG. 6).

Referring to FIG. 7, the swing element 1512 comprises an L-shaped bar 1513, a first projection 1514 and a second projection 1515. The first projection 1514 and the second projection 1515 are respectively connected to two ends of the L-shaped bar 1513. After the horizontal slide member 1511 moves for a distance S1 along the second direction (the −X axial direction), the second projection 1515 enters the underneath of the protruded structure 1334 of the lower clamp mechanism 133, so that the second projection 1515, protruded from the underneath of the protruded structure 1334, is able to lift the protruded structure 1334 upwards to drive the clamp 1332 to move along the third direction (the +Z axial direction). Detailed structure of the second reciprocating assembly 152 and how the second projection 1515 lifts the clamp 1332 will be elaborated below in sequence.

Referring to FIG. 8, an appearance diagram of a second reciprocating assembly of FIG. 4 is shown. The second reciprocating assembly 152 comprises a motherboard 1521, at least one first bump 1522 and a second bump 1523. The motherboard 1521 has a lower surface 1521b facing the −Z axis, and each first bump 1522 is disposed on the lower surface 1521b of the motherboard 1521 and has a second inclined surface 152s1, and an acute angle A1 is formed by the second inclined surface 152s1 and the lower surface 1521b. The second bump 1523 is disposed on the lower surface 1521b of the motherboard 1521 and has a sliding surface 152s2, and an obtuse angle A2 is formed by the sliding surface 152s2 and the lower surface 1521b. In the present example, the second inclined surface 152s1 can be realized by a plane or a curved surface. In the present example, the sliding surface 152s2 is an inclined surface, which can be realized by a plane or a curved surface. In another example, the sliding surface 152s2 can also be realized by a cam profile surface, such as the profile surface of a cam groove.

The second reciprocating assembly 152 has at least one opening 1524, allowing the fixed column 1531 of the upper body 153 (FIG. 4) to pass through, so that the second reciprocating assembly 152 can move along the fixed column 1531. In addition, the second elastic member 155 (FIG. 4) can be disposed between the chassis 1532 of the fixed column 1531 (FIG. 4) and the second reciprocating assembly 152.

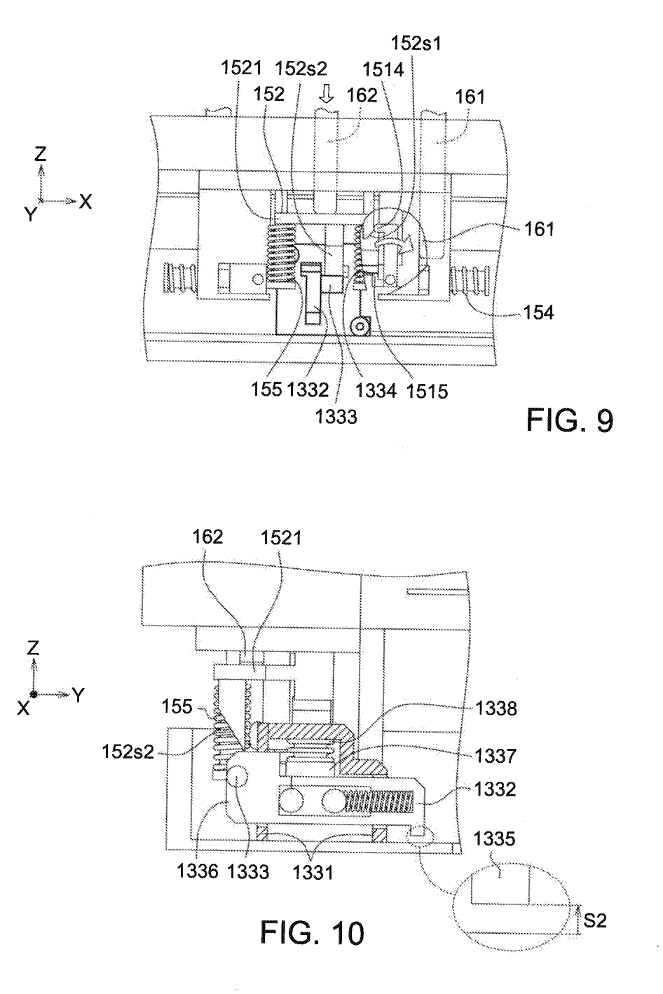

Referring to FIG. 9, a schematic diagram of the push assembly of FIG. 7 driving the second reciprocating assembly to generate a bevel movement is shown. When the second push member 162 of the push assembly 160 pushes the motherboard 1521 of the second reciprocating assembly 152 to move along the first direction (the −Z axial direction), the second inclined surface 152s1 of the second reciprocating assembly 152 and the first projection 1514 of the swing element 1512 generate a bevel movement, which makes the swing element 1512 swing, so that the second projection 1515 drives the protruded structure 1334 to move along the third direction (the +Z axial direction).

During the process of the second inclined surface 152s1 pushing the second reciprocating assembly 152 along the first direction (the −Z axial direction), the second elastic member 155 is deformed and stores the elastic potential energy. During the process of the second inclined surface 152s1 moving along the third direction (the +Z axial direction), the second elastic member 155 releases the elastic potential energy, and drives the second reciprocating assembly 152 to automatically return to the initial position.

Referring to FIG. 10, a side view towards the −X axial direction of FIG. 9 is shown. As the second projection 1515 (FIG. 9) of the swing element 1512 drives the protruded structure 1334 (FIG. 9) to move along the third direction (the +Z axial direction) so as to drive the clamp 1332 to move for a distance S2 along the third direction, the clamp 1332 is up-lifted for the distance S2.

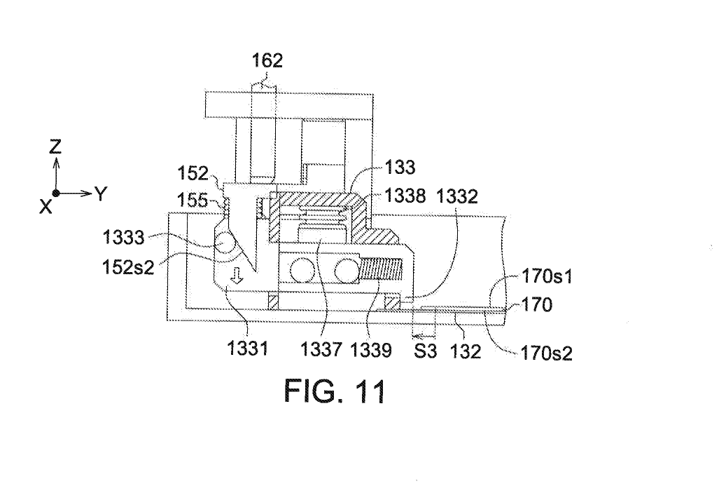

Referring to FIG. 11, a schematic diagram of a push assembly of FIG. 10 pushing the clamp to move along a fourth direction is shown. The second push member 162 of the push assembly 160 continues to push the second reciprocating assembly 152 along the first direction (the −Z axial direction) until the sliding surface 152s2 moves with respect to the cylinder structure 1333, so that the sliding surface 152s2 drives the cylinder structure 1333 to move for a distance S3 along the fourth direction (such as the −Y axial direction) so as to drive the clamp 1332 to move for the distance S3 along the fourth direction. That is, the clamp 1332 is withdrawn for the distance S3 to provide an accommodation space for the substrate 170.

As indicated in FIG. 11, when the clamp 1332 moves for a distance S3 along the fourth direction (the Y axial direction) to provide an accommodation space for the substrate 170, the electrostatic chuck 120 of FIG. 1 places the substrate 170 on the mask 132, wherein the non-coating surface 170s1 of the substrate 170 faces the clamp 1332.

The structure of the lower clamp mechanism 133 is elaborated below. The lower clamp mechanism 133 further comprises a fourth elastic member 1339. The fourth elastic member 1339 connects the lower clamp retainer 1331 with the clamp 1332 along the fourth direction (the Y axial direction). When the clamp 1332 moves with respect to the lower clamp retainer 1331, the fourth elastic member 1339 is deformed and stores the elastic potential energy. Thus, when the sliding surface 152s2 moves along the third direction (the +Z axial direction) to come off the cylinder structure 1333, the fourth elastic member 1339 releases the elastic potential energy, and drives the clamp 1332 to return to the initial position.

The lower clamp mechanism 133 further comprises a movable member 1337 and the third elastic member 1338. The third elastic member 1338 connects the lower clamp retainer 1331 with the movable member 1337 along the first direction (the −Z axial direction). When the clamp 1332 is driven to move along the third direction (the +Z axial direction), the third elastic member 1338 is deformed and stores the elastic potential energy. Thus, during the process of the second inclined surface 152s1 (FIG. 9) being displaced along the first direction (the −Z axial direction), the third elastic member 1338 releases the elastic potential energy, and drives the movable member 1337 to push the clamp 1332 to return to the initial position along the first direction (the −Z axial direction) so as to clamp the substrate 170 on the mask 132.

Then, the mask assembly 130 (FIG. 3) returns to the transmission mechanism 110 (FIG. 3) and is transmitted to an environment of coating process by the transmission mechanism 110. Since the lower clamp mechanism 133 is located on the side of the non-coating surface 170s1 of the substrate 170 and the plasma atmosphere of the subsequent coating process reacts in a direction towards the coating surface 170s2 of the substrate 170 (that is, the surface opposite to the non-coating surface 170s1). Neither will the non-coating surface 170s1 be polluted by plasma coating, nor the lower clamp mechanism 133 will be polluted by the active gas generated from plasma dissociation.

It will be apparent to those skilled in the art that various modifications and variations can be made to the disclosed embodiments. It is intended that the specification and examples will be considered as an exemplar, with a true scope of the disclosure being indicated by the following claims and their equivalents.

What is claimed is:

1. A substrate and mask attachment clamp device, comprising;
a push assembly;
an upper clamp mechanism, comprising:
a first reciprocating assembly, comprising a first inclined surface and a swing element;
a second reciprocating assembly, comprising a second inclined surface and a sliding surface; and
a lower clamp mechanism, comprising:
a lower clamp retainer; and
a clamp movably disposed on the lower clamp retainer;
wherein, during the process of the push assembly moving along a first direction, the push assembly moves with respect to the first inclined surface to drive the first reciprocating assembly to move along a second direction, the push assembly further drives the second inclined surface to move with respect to the swing element so as to drive the clamp to move along a third direction opposite to the first direction and drives the sliding surface to move with respect to the lower clamp mechanism so as to drive the clamp to move along a fourth direction, and the first direction, the second direction and the fourth direction are substantially perpendicular to each other.

2. The substrate and mask attachment clamp device according to claim 1, wherein the clamp presses on a non-coating surface of a substrate.

3. The substrate and mask attachment clamp device according to claim 1, wherein the first reciprocating assembly further comprises:
a horizontal slide member having the first inclined surface and being pivotally connected to the swing element.

4. The substrate and mask attachment clamp device according to claim 1, wherein the swing element comprises:
a first projection; and
a second projection;
wherein, during the process of the push assembly moving along the first direction, the push assembly drives the second inclined surface and the first projection of the swing element to generate a bevel movement, which makes the swing element swing, such that the second projection drives the clamp to move along the third direction.

5. The substrate and mask attachment clamp device according to claim 4, wherein the lower clamp mechanism comprises a protruded structure connected to the clamp, and the second projection, from the underneath of the protruded structure, drives the clamp to move along the third direction.

6. The substrate and mask attachment clamp device according to claim 1, wherein the upper clamp mechanism further comprises:
an upper body; and
a first elastic member connecting the upper body with the first reciprocating assembly, wherein when the first reciprocating assembly moves, the first elastic member is deformed and stores the elastic potential energy.

7. The substrate and mask attachment clamp device according to claim 1, wherein the upper clamp mechanism further comprises:
an upper body; and
a second elastic member connecting the upper body with the second reciprocating assembly, wherein when the second reciprocating assembly moves, the second elastic member is deformed and stores the elastic potential energy.

8. The substrate and mask attachment clamp device according to claim 1, wherein the lower clamp mechanism further comprises:
a movable member; and
a third elastic member connecting the lower clamp retainer with the movable member along the first direction, wherein when the clamp moves, the third elastic member is deformed and stores the elastic potential energy.

9. The substrate and mask attachment clamp device according to claim 1, wherein the lower clamp mechanism further comprises:
a fourth elastic member connecting the lower clamp retainer with the clamp along the fourth direction, wherein when the clamp moves, the fourth elastic member is deformed and stores the elastic potential energy.

10. The substrate and mask attachment clamp device according to claim 7, wherein the lower clamp mechanism comprises a cylinder structure, the sliding surface moves with respect to the cylinder structure to drive the clamp to move along the fourth direction.

11. The substrate and mask attachment clamp device according to claim 1, wherein the sliding surface is an inclined surface or a cam profile surface.

12. The substrate and mask attachment clamp device according to claim 1, further comprises:
a mask assembly, comprising the lower clamp mechanism, a frame and a mask, wherein the frame has a non-coating surface, and the mask and the lower clamp mechanism are disposed on the non-coating surface of the frame.

13. The substrate and mask attachment clamp device according to claim 12, comprising:
a plurality of lower clamp mechanisms disposed on an edge of the frame.

14. The substrate and mask attachment clamp device according to claim 12, further comprising:
a transmission mechanism transmitting the mask assembly to an position of the upper clamp mechanism.
